(19) United States
(12) Patent Application Publication
(10) Pub. No.: US 2012/0249503 A1
(43) Pub. Date: Oct. 4, 2012

(54) DISPLAY AND ELECTRONIC DEVICE

(75) Inventors: Shinichi Teraguchi, Kanagawa (JP); Keisuke Omoto, Kanagawa (JP); Hirohisa Koriyama, Kanagawa (JP); Yoko Fukunaga, Kanagawa (JP); Toshiaki Arai, Kanagawa (JP); Kazuyuki Endou, Kanagawa (JP)

(73) Assignee: Sony Corporation, Tokyo (JP)

(21) Appl. No.: 13/413,057

(22) Filed: Mar. 6, 2012

(30) Foreign Application Priority Data
Mar. 30, 2011 (JP) 2011-075725

(51) Int. Cl. G09G 3/04; G09G 3/30; G09G 3/36; G09G 5/00

(52) U.S. Cl. 345/206; 345/35; 345/80; 345/87

(57) ABSTRACT

A display capable of reducing an electric effect of a color filter on a pixel circuit, and thereby suppressing degradation in display quality is provided. The display includes a pixel drive substrate having a color filter, a display function layer provided on the pixel drive substrate, a first electrode and a second electrode to supply a drive voltage to the display function layer, and a third electrode disposed to face the color filter.

### BACKGROUND

The present disclosure relates to a display and an electronic device displaying a color image.

In an image display, such as an organic electroluminescent (EL) display and a liquid crystal display, a color filter colored with a pigment is provided in a display panel to perform color-image display. In recent years, there has been developed a display using a Color Filter on Array (COA) technique in which such a color filter is disposed on a pixel drive substrate.

However, in a case where a color filter is provided on a pixel drive substrate, a coloring material included in the color filter may cause a so-called dielectric dissipation factor and have an electric effect on a pixel circuit. As a result, a display potential in the pixel circuit fluctuates, causing an inconvenience of degrading display quality. Further, in a display having a liquid crystal layer driven for display in a horizontal electric field mode, even when a color filter is provided on a counter board side, a similar inconvenience is caused because an electric field is produced to cross the color filter.

Thus, there has been suggested a technique of reducing an effect on display quality, by using a specific coloring material at a specific density which makes the dielectric dissipation factor in a color filter equal to or less than a predetermined value (International Publication No. WO09/087,886). Further, there has been also suggested a technique of reducing the above-described effect, by reducing the thickness of a color filter of a specific color (G) which is said to have a relatively large effect on the dielectric dissipation factor (by disposing the color filter at a position away from an electric field), in a liquid crystal display of the horizontal electric field mode (Japanese Unexamined Patent Application Publication No. 2088-249947).

### SUMMARY

Recently, improvements in color reproduction range have been in increasing demand, and for this demand, it is desirable to increase the density of a coloring material in a color filter. However, in the technique of International Publication No. WO09/087,886 described above, the dielectric dissipation factor is maintained at a constant value or less by specifying the coloring material and its density and therefore, it is extremely difficult to suppress the dielectric dissipation factor while improving the color reproduction range by increasing the density of the coloring material. On the other hand, it is difficult to apply the technique of Japanese Unexamined Patent Application Publication No. 2008-249947 to a structure using the COA technique. Therefore, it is expected that a technique of reducing an electric effect (for example, an effect of the dielectric dissipation factor) on a pixel circuit by disposing a color filter will be realized.

In view of the foregoing, it is desirable to provide a display and an electronic device which may reduce an electric effect of a color filter on a pixel circuit, thereby suppressing degradation in display quality.

According to an embodiment of the present disclosure, there is provided a display including: a pixel drive substrate having a color filter; a display function layer provided on the pixel drive substrate; a first electrode and a second electrode to supply a drive voltage to the display function layer; and a third electrode disposed to face the color filter.

In the display according to the above-described embodiment of the present disclosure, on the pixel drive substrate having the color filter, the third electrode is provided to face the color filter, besides the first electrode and the second electrode driving the display function layer. Supplying the third electrode with the electric potential reduces an effect exerted by the behavior of impurity ions in the color filter, and makes it difficult to cause a fluctuation in a display potential retained in a pixel circuit, even when a dielectric dissipation factor is produced by the color filter.

According to an embodiment of the present disclosure, there is provided an electronic device including the display including: a pixel drive substrate having a color filter; a display function layer provided on the pixel drive substrate; a first electrode and a second electrode to supply a drive voltage to the display function layer; and a third electrode disposed to face the color filter.

According to the electronic device and the display in the embodiments of the present disclosure, the third electrode is provided to face the color filter on the pixel drive substrate having the color filter, in addition to the first electrode and the second electrode driving the display function layer and thus, it is possible to suppress the fluctuation in the display potential retained in the pixel circuit, even when the dielectric dissipation factor is produced by the color filter. Therefore, an electric effect of the color filter on the pixel circuit may be reduced and thereby degradation in display quality may be suppressed.

It is to be understood that both the foregoing general description and the following detailed description are exemplary, and are intended to provide further explanation of the technology as claimed.

### BRIEF DESCRIPTION OF THE DRAWINGS

The accompanying drawings are included to provide a further understanding of the disclosure, and are incorporated in and constitute a part of this specification. The drawings illustrate embodiments and, together with the specification, serve for explaining the principles of the technology.

FIG. 1 is a cross-sectional diagram illustrating a schematic configuration of an organic EL display according to a first embodiment of the present disclosure.

FIG. 2 is a functional block diagram illustrating an example of a pixel driving circuit in the organic EL display illustrated in FIG. 1.

FIG. 3 is a diagram illustrating a circuit configuration of a pixel illustrated in FIG. 2.

FIG. 4 is a cross-sectional diagram illustrating a schematic configuration of an organic EL display according to a comparative example.

FIG. 5 is a diagram illustrating a color-filter equivalent circuit, with a pixel circuit (an organic EL device).

FIGS. 6A and 6B are schematic diagrams for explaining effects of a color filter on the pixel circuit in the comparative example.

FIGS. 7A and 7B are schematic diagrams for explaining effects produced by providing a third electrode.

FIG. 8 is a characteristic diagram illustrating changes in cathodic current with time in an example and the comparative example.

FIG. 9 is a schematic diagram for explaining a shielding effect in a modification 1.

FIG. 10 is a cross-sectional diagram illustrating a schematic configuration of an organic EL display according to a second embodiment of the present disclosure.

FIG. 11 is a schematic diagram illustrating an example of a plane structure of an electrode layer illustrated in FIG. 10.

FIG. 12 is a schematic diagram for explaining an electric effect in the second embodiment.

FIG. 13 is a cross-sectional diagram illustrating a schematic configuration of a liquid crystal display according to a third embodiment of the present disclosure.

FIG. 14 is a functional block diagram illustrating an example of peripheral circuits in the liquid crystal display illustrated in FIG. 13.

FIG. 15 is a diagram illustrating a circuit configuration of a pixel illustrated in FIG. 14.

FIG. 16 is a diagram illustrating a color-filter equivalent circuit, with a pixel circuit (a liquid crystal display device).

FIG. 17 is a cross-sectional diagram illustrating a schematic configuration of a liquid crystal display according to a fourth embodiment of the present disclosure.

FIG. 18 is a cross-sectional diagram illustrating a schematic configuration of a liquid crystal display according to a fifth embodiment of the present disclosure.

FIG. 19 is a cross-sectional diagram illustrating a schematic configuration of a liquid crystal display according to a sixth embodiment of the present disclosure.

FIG. 20 is a plan view illustrating a schematic configuration of a module including the display in each of the above-described embodiments and the like.

FIG. 21 is a perspective diagram illustrating an appearance of an application example 1.

FIGS. 22A and 22B are perspective diagrams illustrating an appearance of an application example 2 when viewed from front, and an appearance when viewed from back, respectively.

FIG. 23 is a perspective diagram illustrating an appearance of an application example 3.

FIG. 24 is a perspective diagram illustrating an appearance of an application example 4.

FIGS. 25A to 25G are views of an application example 5, namely, a front view in an open state, a side view in the open state, a front view in a closed state, a left-side view, a right-side view, a top view, and a bottom view, respectively.

### DETAILED DESCRIPTION OF EMBODIMENTS

Embodiments of the present disclosure will be described below in detail with reference to the drawings. It is to be noted that the description will be provided in the following order.

1. First embodiment (an example of an organic EL display in which a color filter is interposed between a first electrode (anode) and a third electrode (at the same potential as the first electrode), on a drive substrate)
2. Modification 1 (an example of a case where a fixed potential is supplied to a third electrode)
3. Second embodiment (an example of an organic EL display in which, on a drive substrate side, a third electrode is provided at the same layer as a first electrode (anode) on a color filter)
4. Third embodiment (an example of a liquid crystal display in which a color filter is interposed between a first electrode (pixel electrode) and a third electrode, on a drive substrate side)
5. Fourth embodiment (an example of a liquid crystal display in which, on a drive substrate side, a third electrode is provided at the same layer as a first electrode (pixel electrode) on a color filter)
6. Fifth embodiment (an example of a liquid crystal display (horizontal electric field mode) in which a color filter is interposed between a first electrode and a third electrode, on a drive substrate side)
7. Sixth embodiment (an example of a liquid crystal display (horizontal electric field mode) in which, on a drive substrate side, a third electrode is provided at the same layer as a second electrode (common electrode) on a color filter)
8. Application examples (examples of application of a display to an electronic device)

### First Embodiment

### (Configurational Example of Organic EL Display 1)

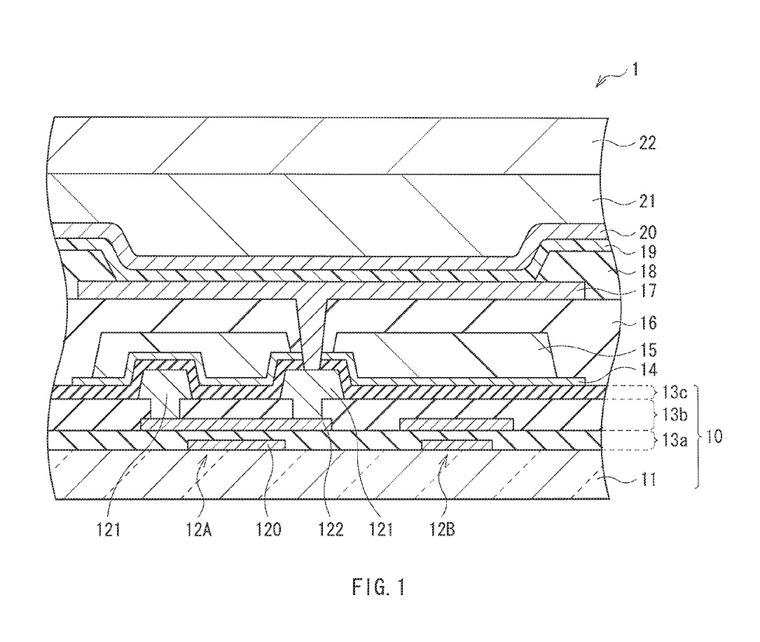

FIG. 1 illustrates a cross-sectional configuration of an organic EL display 1 according to the first embodiment of the present disclosure. The organic EL display 1 has a configuration in which a color filter (a color filter 15) is provided on a drive substrate 10 side by a so-called COA technique, and causes light emission by a bottom emission (light emission at bottom) method. In this organic EL display 1, for example, a plurality of organic EL devices are arranged, for instance, in the form of a matrix on the drive substrate 10, as pixels of R (red), G (green), and B (blue). It is to be noted that only a region corresponding to one pixel is illustrated in FIG. 1.

### (Pixel Configuration)

The drive substrate 10 is a circuit board provided with pixel driving circuits (to be described later) driving the above-mentioned pixels, transistors, and the like. In this drive substrate 10, a transistor section 12A (equivalent to transistors Tr1 and Tr2 to be described later) and a capacitive section 12B (equivalent to a capacitive element Cs to be described later) are provided on a transparent substrate 11 made of, for example, glass or plastic. In the transistor section 12A, for example, a gate electrode 120, a gate insulating film 13a, a semiconductor layer 122, an interlayer insulating film 13b, and a source/drain electrode 121 are laminated in this order on a the substrate 11. This source/drain electrode 121 is covered by an interlayer insulating film 13c, and electrically connected to a first electrode 17 (anode) via a contact hole provided in the interlayer insulating film 13c. It is to be noted that the configuration of a pixel circuit will be described later.

In the present embodiment, on such a drive substrate 10, the color filter 15 colored with any of R, G, and B colors is provided for every pixel with a third electrode 14 in between. In other words, under the color filter 15, the third electrode 14 is provided to face the color filter 15. This third electrode 14 is supplied with, for example, an electric potential (V1) that is the same as that of the first electrode (anode) 17 to be described later (maintained at the same potential as that of the first electrode 17). Here, the third electrode 14 is provided across the entire region of the color filter 15, while covering the source/drain electrode 121 in the transistor section 12A. However, in each pixel, the third electrode 14 may be provided across the entire region of the color filter 15, or may be provided selectively in a region including at least a region facing the transistor section 12A (or the capacitive section 12B, or both of these sections), for example. On the color filter 15, a planarizing film 16 is formed.

The color filter 15 is a filter in which, for example, any of coloring materials of a red pigment, a green pigment, and a blue pigment is included in a photosensitive resin. Alternatively, a coloring material of other color, e.g., an orange pigment, a purple pigment, or the like may be included. As the blue pigment and the green pigment, a material containing copper phthalocyanine may be used, for example. The copper phthalocyanine exhibits photoconductivity, and has a property of changing a dielectric dissipation factor by a photoconductive effect as will be described later.

Like the first electrode 17, the third electrode 14 is configured using a transparent conductive film made of ITO, IZO, or the like. In the present embodiment, the first electrode 17 to be described later is electrically connected to this third electrode 14, and maintained at the same potential as that of the first electrode 17.

On the planarizing film 16, the first electrode 17 is disposed to establish conduction (to be connected electrically via a contact hole of the planarizing film 16) with the third electrode 14 described above. On this first electrode 17, a pixel separation film (window film) 18 having an aperture is provided, and an organic EL layer 19 is formed in the aperture of the pixel separation film 18. On the organic EL layer 19, a second electrode 20 is provided as an electrode common to all pixels.

The first electrode 17 is provided for every pixel, and functions as an anode to perform hole injection into the organic EL layer 19. The first electrode 17 is configured using a transparent conductive film, which is, for example, a single-layer film made of either indium tin oxide (ITO) or indium zinc oxide (IZO), or a laminated film made thereof.

The pixel separation film 18 is provided to partition a light emitting region of the pixel, and configured using, for example, a photosensitive resin.

The organic EL layer 19 is, for example, a white-light emitting layer that is common to each pixel and emits white light by electron-hole recombination. However, the organic EL layer 19 is not limited to such a white-light emitting layer, and a light emitting layer of each color (a red-light emitting layer, a green-light emitting layer, and a blue-light emitting layer) may be colored for each pixel.

The second electrode 20 is an electrode common to each pixel, and functions, for example, as a cathode performing electron injection into the organic EL layer 19. This second electrode 20 is configured using, for example, a simple substance or an alloy of a metallic material having reflectivity, such as silver (Ag), aluminum (Al), molybdenum (Mo), and chromium (Cr). Alternatively, the second electrode 20 may be configured using a single-layer film made of a magnesium-silver (Mg—Ag) co-deposited film, or a laminated film made thereof.

It is to be noted that between the first electrode 17 and the organic EL layer 19, for example, a hole injection layer or a hole transport layer (neither is illustrated) may be provided, and between the second electrode 20 and the organic EL layer 19, for example, an electron injection layer or an electron transport layer (neither is illustrated) may be provided.

On the second electrode 20, a protective layer 21 to seal and protect the pixels is provided, and on this protective layer 21, a sealing substrate 22 is laminated via an adhesive layer not illustrated. The protective layer 21 is made of, for example, a silicon oxide film, a silicon nitride film etc.

### (Peripheral Circuit Configuration)

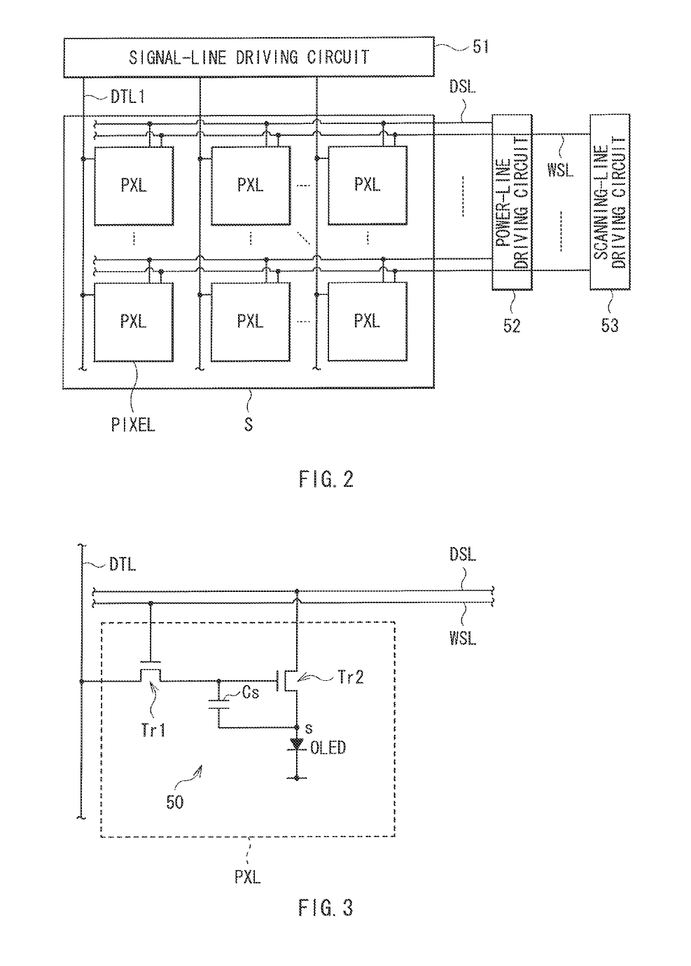

FIG. 2 illustrates a configurational example of peripheral circuits (drivers) of the pixels. In a display region (an effective display region) S, pixels (PXL) are arranged two-dimensionally in the form of a matrix, for example, and around this display region S, a scanning-line driving circuit 53, a power-line driving circuit 52, and a signal-line driving circuit 51 are arranged. Each of the pixels (PXL) is connected to a scanning line WSL, a power line DSL, and a signal line DTL.

The scanning-line driving circuit 53 sequentially selects each pixel, by sequentially applying a selection pulse to the two or more scanning lines WSL on predetermined timing. Specifically, the scanning-line driving circuit 53 outputs a voltage Von to set the write transistor Tr1, which will be described later, in an ON state and a voltage Voff to set the write transistor Tr1 in an OFF state, by switching these voltages in a time sharing manner.

The power-line driving circuit 52 controls light-emission operation and extinction operation of each pixel, by sequentially applying a control pulse to the two or more power lines DSL on predetermined timing. Specifically, the power-line driving circuit 52 outputs a voltage VH to cause a flow of a current Ids in the driving transistor Tr2 to be described later and a voltage VL to prevent the current Ids from flowing, by switching these voltages in a time sharing manner.

The signal-line driving circuit 51 generates an analog image signal corresponding to an image signal S inputted externally, on predetermined timing, and applies the generated signal to each of the signal lines DTL. This allows writing of the image signal into the pixel selected by the scanning-line driving circuit 53. It is to be noted that the drive substrate 10 is provided with, for example, circuits such as an image-signal processing circuit that subjects an image signal to predetermined correction processing and a timing control circuit that controls display drive timing (neither is illustrated), in addition to the above-described elements.

### (Pixel Circuit Configuration)

FIG. 3 illustrates an example of a circuit configuration of the pixel (PXL). A pixel circuit 50 includes the organic EL device (OLED), the write transistor Tr1, (for sampling), the driving transistor Tr2, and a retention capacitive element Cs. Each of the write transistor Tr1 and the driving transistor Tr2 is, for example, an n-channel MOS (Metal Oxide Semiconductor) TFT. The type of the TFT is not limited in particular, and may be, for example, an inverted staggered structure (a so-called bottom gate type) or a staggered structure (a so-called top gate type).

In each of the pixels, a gate of the write transistor Tr1 is connected to the scanning line WSL, and a drain (or a source) is connected to the signal line DTL, and the sauce (or the drain) is connected to a gate of the driving transistor Tr2 and one end of the retention capacitive element Cs. A drain (or a source) of the driving transistor Tr2 is connected to the power line DSL, and the sauce (or the drain) is connected to the other end of the retention capacitive element Cs and an anode of the organic EL device (OLED). A cathode of the organic EL device (OLED) is set at a fixed potential, and here, set to a ground (grounding electric potential).

### [Operation and Effects of Organic EL Display 1]

### (Image Display Operation)

With reference to FIG. 1 to FIG. 3, image display operation in the organic EL display 1 will be described. In the organic EL display 1, when an image signal is inputted, the scanning-line driving circuit 53, the power-line driving circuit 52, and the signal-line driving circuit 51 drive each of the pixels (PXL) in the display region S for display. This causes a driving current to flow in the organic EL device (OLED) in each of the pixels, and thereby white-light emission takes place by electron-hole recombination in the organic EL layer 19.

Specifically, in the pixel circuit 50 illustrated in FIG. 3, operation of writing the image signal is performed as follows. When an image signal voltage is supplied to the signal line DTL and the predetermined voltage VH is supplied to the power line DSL, the scanning-line driving circuit 53 increases the voltage of the scanning line WSL from the voltage Voff to the voltage Von. This causes the write transistor Tr1 to be in the ON state and thus, a gate potential Vgs of the driving transistor Tr2 rises to an image signal voltage corresponding to the voltage of the signal line DTL at this time. As a result, the image signal voltage is written to the capacitive element Cs and retained.

Subsequently, the scanning-line driving circuit 53 lowers the voltage of the scanning line WSL from the voltage Von to the voltage Voff. This causes the write transistor Tr1 to be in the OFF state, and the gate of the driving transistor Tr2 enters a floating state. As a result, in a state in which the voltage Vgs between the gate and the source of the driving transistor Tr2 is held constantly, the current Ids flows between the drain and the source of the driving transistor Tr2. This makes the anode voltage of the organic EL device (OLED) become greater than a predetermined threshold voltage, and the current Ids corresponding to the image signal voltage retained in the capacitive element Cs, namely, the voltage Vgs between the gate and the source in the driving transistor Tr2, flows between the anode and the cathode of the organic EL device, and thereby the organic EL device (OLED) emits light.

Of the light (for example, white light) thus emitted from the organic EL layer 19, light reflected off the second electrode 20 and light emitted from the organic EL layer 19 directly toward the first electrode 17 are taken out from a lower part of the drive substrate 10 as predetermined color light, after passing through the first electrode 17 and then the color filter 15. In this way, the light emission in the bottom emission method is performed, and thereby color image display is carried out.

### (Effect of Color Filter on Pixel Circuit)

Here, an electric effect on a pixel circuit when a color filter is provided on a drive substrate side will be described by using a comparative example.

### COMPARATIVE EXAMPLE

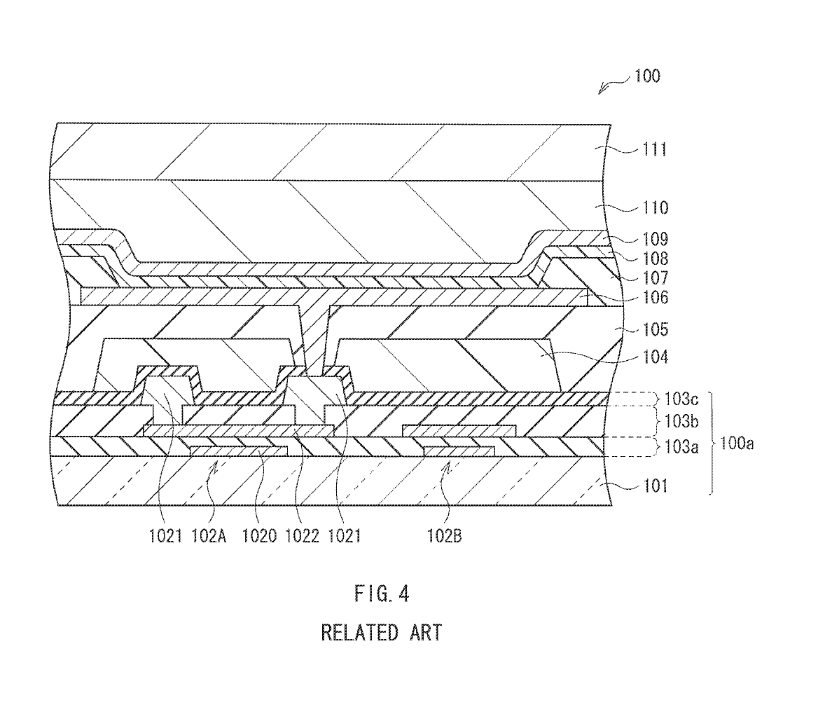

FIG. 4 illustrates a cross-sectional structure of an organic EL display (an organic EL display 100) according to the comparative example. Like the organic EL display 1 of the present embodiment, the organic EL display 100 performs light emission in a bottom emission method, and has a configuration in which a color filter is provided on a drive substrate side. Specifically, on a transparent substrate 101, a color filter 104 including a pigment is provided on a drive substrate 100a having a transistor section 102A and a capacitive section 102B, and these are planarized by a planarizing film 105. In the transistor section 102A, a gate electrode 1020, a gate insulating film 103a, a semiconductor layer 1022, an interlayer insulating film 103b, and a source/drain electrode 1021 are laminated in this order. The source/drain electrode 1021 is covered by an interlayer insulating film 103c. On the planarizing film 105, a first electrode 106 serving as an anode is disposed. At an aperture part of a pixel separation film 107 on the first electrode 106, an organic EL layer 108 is formed, and on this organic EL layer 108, a second electrode 109 serving as a cathode is provided. In this way, the organic EL display 100 has a configuration in which the color filter 104 is provided on dielectrics such as the interlayer insulating film 103b, in a region facing the transistor section 102A and the capacitive section 102B.

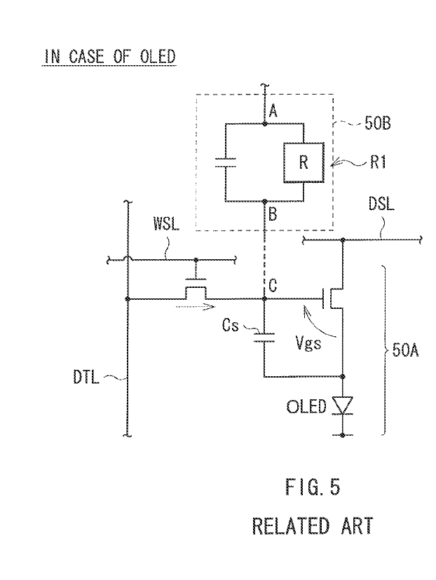

When the color filter 104 is thus provided on the drive substrate 100a side, an equivalent circuit is formed at a pixel circuit by the color filter 104, and a circuit configuration as illustrated in FIG. 5 is obtained. In other words, there is obtained a circuit configuration in which a color-filter equivalent circuit 50B is connected to a holding voltage section (a point C in FIG. 5) of a pixel circuit (a pixel circuit 50A) including a write transistor Tr1, a driving transistor Tr2, an organic EL device (OLED), and a retention capacitive element Cs. At the time of image display, as described above, a voltage Vgs between a gate and a source in the driving transistor Tr2 is determined according to an image signal voltage, and light emission takes place by supplying the organic EL layer with a driving current according to the voltage Vgs between the gate and the source. However, forming the color-filter equivalent circuit 50B as described above causes the following inconvenience.

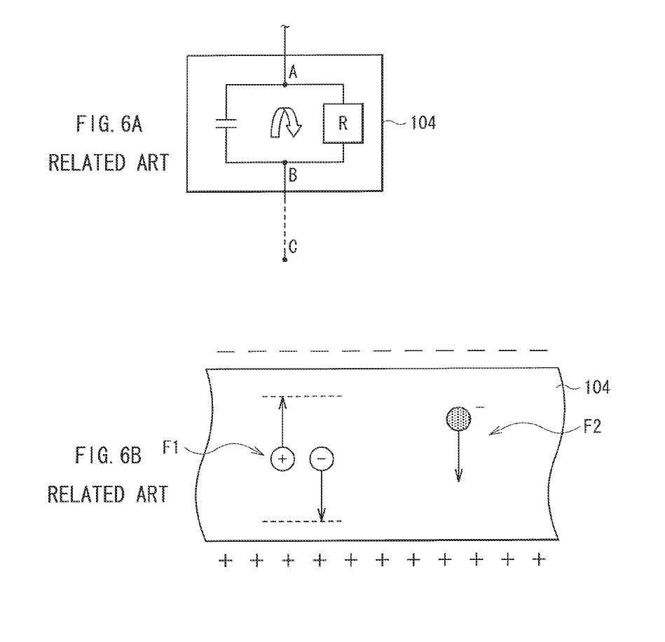

Specifically, in the color-filter equivalent circuit 50B, as illustrated in FIG. 6A, a so-called dielectric dissipation factor is provided (a resistance component R1 is formed) due to the pigment included in the color filter 104. Therefore, an electric potential of each of points A and B in the color-filter equivalent circuit 50B fluctuates due to the dielectric dissipation factor by the color filter 104, even when the electric potential at the point C is once determined as the electric potential according to the image signal voltage in the manner described above. As a result, a holding potential in the pixel circuit 50A (the electric potential at the point C) fluctuates. In addition, the pigment of the color filter has a photoconductive effect, and because of this, the dielectric dissipation factor also changes (increases). In other words, due to the photoconductive effect affected by the OLED light emission and the like, the regulation of the holding potential increases.

Further, carriers (hole and electron) are produced in the color filter 104, by the photoconductive effect of the pigment. As illustrated in FIG. 6B, the carriers move when affected by an external electric field and the like (F1), and are captured by a defect and the like and accumulated locally. As a result, for example, in the transistor section 12A, a leakage current due to a backgating effect and the like increases, causing a fluctuation in the holding potential.

Furthermore, because a conductive additive and impurity ions are included in such a pigment, it is conceivable that the impurity ions and the like may move due to the external electric field (F2 in FIG. 6B) and further, may scatter to the periphery, which may cause a fluctuation in a property of, for example, the transistor section 12A or the like, thereby causing a fluctuation in the holding potential by the leakage current.

For the above-described reasons, a fluctuation in the holding potential in the pixel circuit 50A occurs, causing image degradation. For example, a decline in cathodic current causes a decrease in luminance, and in particular, a decline in cathodic current in a pixel G is intense, which causes image degradation such as a color shift.

### (Effects by Provision of Third Electrode)

In contrast, in the present embodiment, on the drive substrate 10, an electrode (the third electrode 14) different from the first electrode 17 and the second electrode 20 is provided to face the color filter 15 (to interpose the color filter 15 between the third electrode 14 and the first electrode 17). This third electrode 14 may be supplied with the same potential as that of the first electrode 17, and here, the third electrode 14 is electrically connected to the first electrode 17, and it is possible to maintain the third electrode 14 at the same potential as that of the first electrode 17 (the electric potential corresponding to the image signal).

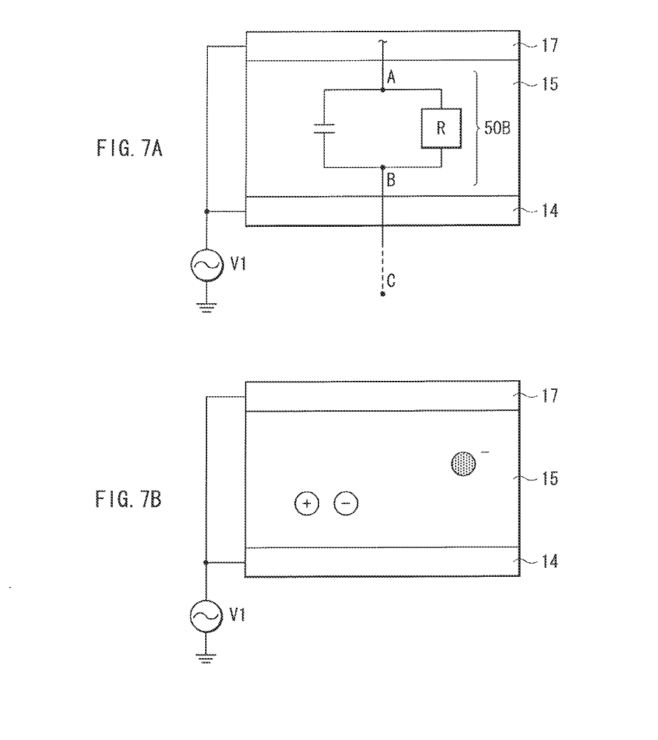

This prevents the electric potential in the point C from fluctuating, by a shielding effect (a so-called effect by an electromagnetic shield) with the third electrode 14 and the first electrode 17, even when the above-described dielectric dissipation factor (and an increase in the dielectric dissipation factor by the photoconductive effect) is produced by the provision of the color filter 15, as illustrated in FIG. 7A. Further, since the color filter 15 is interposed between equipotential surfaces, the movement of the carriers produced by the photoconductive effect, and the movement (diffusion) of the impurity ions and the like are suppressed, as illustrated in FIG. 7B. Furthermore, the effect due to the behavior of the impurity ions as described above may be exerted upon not only the transistor section but also the organic EL layer 19 on an upper part, but such an effect may also be reduced by the shielding effect with the third electrode 14 and the first electrode 17.

As a result, in the present embodiment, an electric effect on the pixel circuit 50 due to the color filter 15 is suppressed.

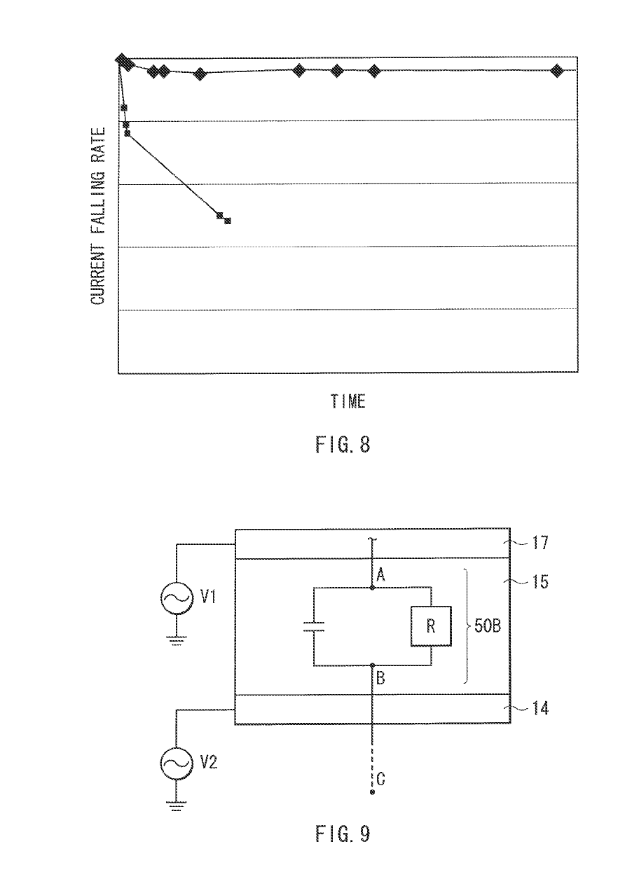

For example, FIG. 8 illustrates a normalized quantity of decline in the cathodic current in the pixel G in each of the configuration of the comparative example and the structure of the present embodiment (example). As illustrated, in the comparative example, the cathodic current exhibits a tendency to decrease with the passage of time, but it is apparent that in the present embodiment in which the third electrode 14 as described above is adopted, the decline in electric current is suppressed.

As described above, the present embodiment has such a configuration that in addition to the first electrode 17 and the second electrode 20 to supply the driving current to the organic EL layer 19, the third electrode 14 is provided, in the configuration in which the color filter 15 is provided on the drive substrate 10 side. This makes it possible to suppress a fluctuation in the holding potential in the pixel circuit 50 by the electrical shielding effect with the first electrode 17 and the third electrode 14, even when the dielectric dissipation factor is produced due to the color filter 15. Therefore, it is possible to reduce the electric effect of the color filter on the pixel circuit and suppress degradation in display quality.

In particular, since the color filter 15 is interposed between the equipotential surfaces by the supply of the same potential as that of the first electrode 17 to the third electrode 14, the above-described shielding effect may be produced, and moreover, the movements of the carriers and the impurity ions in the color filter 15 may be suppressed. Therefore, it is possible to suppress the electric effect on the pixel circuit 50 more effectively.

Next, a modification (a modification 1) of the organic EL display of the first embodiment will be described. In the following, elements similar to those of the organic EL display 1 of the first embodiment will be provided with the same reference characters as those of the first embodiment, and the description will be omitted as appropriate.

### [Modification 1]

In the first embodiment described above, the third electrode 14 is provided under the color filter 15 and this third electrode 14 is maintained at the same potential as that of the first electrode 17, on the drive substrate 10. However, the electric potential to be supplied to the third electrode 14 may not be the same as that of the first electrode 17. For example, as illustrated in FIG. 9, an electric potential V1 corresponding to an image signal may be supplied to a first electrode 17, while a fixed potential V2 different from the electric potential V1 may be supplied to a third electrode 14. Further, this fixed potential V2 may be the same as a cathodic potential, and in that case, the third electrode 14 may be electrically connected to a second electrode 20.

In this way, even in a case where the fixed potential V2 different from the electric potential of the image signal is supplied to the third electrode 14, an electric potential at a point C is prevented from fluctuating by a shielding effect with the third electrode 14 and the first electrode 17, even when a dielectric dissipation factor (and an increase in the dielectric dissipation factor by a photoconductive effect) is produced by a color filter 15, like the first embodiment described above. Therefore, it is possible to obtain effects approximately equal to those of the first embodiment. However, the first embodiment in which the first electrode 17 and the third electrode 14 are at the same potential may suppress the movement of the carriers, the impurity ions, and the like as described above, and thus may suppress the fluctuation in the holding potential in the pixel circuit 50 more effectively.

### Second Embodiment

Next, a display (an organic EL display 2) according to the second embodiment of the present disclosure will be described. Elements similar to those of the organic EL display 1 of the first embodiment will be provided with the same reference characters as those of the first embodiment, and the description will be omitted as appropriate.

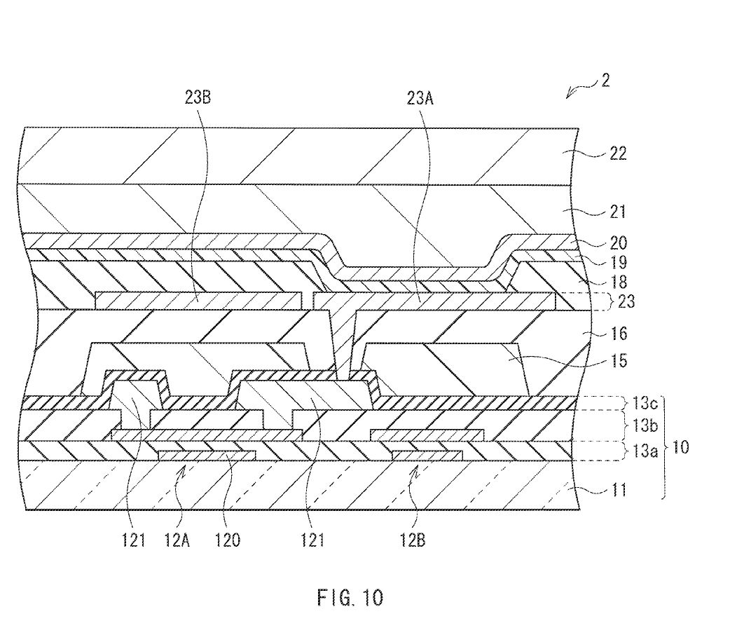

FIG. 10 illustrates a cross-sectional structure of the organic EL display 2. Like the organic EL display 1 of the first embodiment, the organic EL display 2 has a configuration in which a color filter 15 is provided on a drive substrate 10 side by a so-called COA technique, and has a plurality of organic EL devices causing light emission in a bottom emission method as pixels. In addition, configurations of a pixel driving circuit and a pixel circuit are similar to those in the first embodiment.

In the organic EL display 2, the color filter 15 is provided on the drive substrate 10, like the first embodiment. On this color filter 15, a planarizing film 16 is provided, and on this planarizing film 16, an electrode layer 23 including an anode layer, a pixel separation film 18, an organic EL layer 19, and a second electrode 20 serving as an anode are laminated.

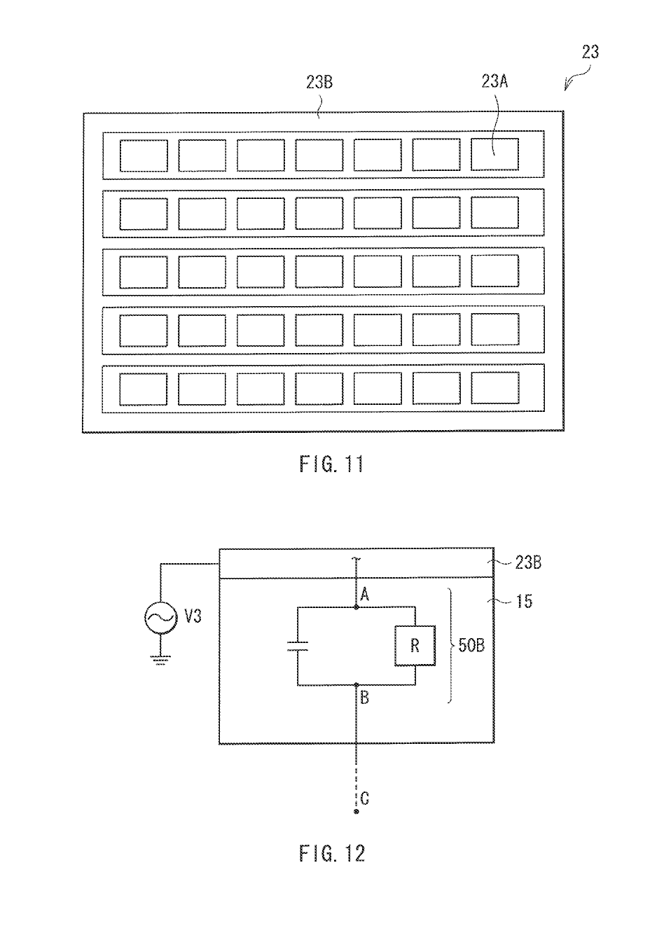

However, in the present embodiment, unlike the first embodiment, a third electrode (a third electrode 23B) is not provided under the color filter 15, but provided above the color filter 15 while facing the color filter 15, on the drive substrate 10. In other words, the electrode layer 23 disposed on the planarizing film 16 has a part (a first electrode 23A) functioning as the anode and a part (the third electrode 23B) electrically shielding the color filter 15 (the electrode layer 23 is separated into the first electrode 23A and the third electrode 23B). FIG. 11 illustrates an example of a plane configuration (a layout configuration on a surface parallel to a substrate surface) of the electrode layer 23. As illustrated, in the electrode layer 23, the third electrode 23B is disposed to surround the first electrodes 23A that are provided in the form of a matrix, for example.

In such an electrode layer 23, the first electrode 23A is connected to a source/drain electrode 121 of a transistor section 12A, and thereby an electric potential (for example, a positive potential) corresponding to an image signal is supplied to the first electrode 23A. On the other hand, the third electrode 23B is electrically separated from the first electrode 23A while electrically connected to the second electrode 20, for example, and is supplied with the same potential as a cathodic potential (e.g., a negative potential or 0 V). For example, in a peripheral section of the electrode layer 23 as illustrated in FIG. 11, the third electrode 23B is electrically connected to the second electrode 20 (cathode).

It is to be noted that the third electrode 23B may not be maintained at the cathodic potential and may be supplied with, for example, a fixed potential different from the cathodic potential. However, it is desirable to supply an electric potential different from the electric potential supplied to the first electrode 23A, in terms of positive and negative.

In the present embodiment, thanks to the above-described configuration, light emission by a bottom emission method takes place and color image display is performed, like the first embodiment. Further, since the third electrode 23B is provided to face the color filter 15, it is possible to reduce an electric effect on the pixel circuit 50. Specifically, in the present embodiment, as illustrated in FIG. 12, for example, the third electrode 23B on the color filter 15 is provided, and a predetermined fixed potential V3 (for example, a cathodic potential) is supplied to the third electrode 23B.

Here, the first electrode 23A serving as the anode is provided on the color filter 15 with a dielectric (the planarizing film 16) in between and thus, in a region facing the first electrode 23A, the electric potential (a positive electric field of tens of volts) corresponding to the image signal is applied. In such a state, the third electrode 23B is supplied with an electric potential (here, the cathodic potential) that is different in terms of positive and negative from the electric potential supplied to the first electrode 23A, thereby obtaining an effect equivalent to the electromagnetic shield, which is to reduce an effect of the transistor section 12A by reversing the behavior of electrically-charged impurities. This makes it possible to suppress a fluctuation in holding potential caused by a characteristic change of the transistor section 12A. In addition, it is also possible to reduce an adverse effect on the organic EL layer 19 resulting from diffusion of impurities. Therefore, it is possible to obtain effects approximately equal to those of the first embodiment.

### Third Embodiment

Next, there will be described a display (a liquid crystal display 3) according to the third embodiment of the present disclosure. In each of the first and second embodiments, the organic EL display has been taken as an example of the display according to the embodiment of the present disclosure, but application to a liquid crystal display is also possible as will be described below. It is to be noted that elements similar to those of the organic EL display 1 in the first embodiment are provided with the same reference characters as those of the first embodiment, and the description will be omitted as appropriate.

### (Pixel Configuration)

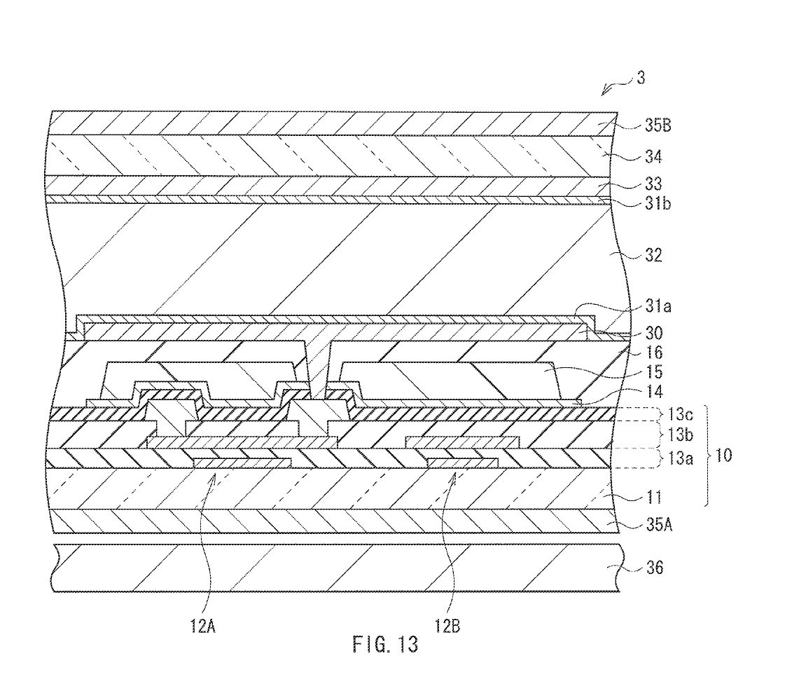

FIG. 13 illustrates a cross-sectional configuration of the liquid crystal display 3. For instance, the liquid crystal display 3 has a plurality of liquid crystal display devices arranged, for example, in the form of a matrix, on a drive substrate 10, as pixels of R (red), G (green), and B (blue). It is to be noted that FIG. 13 illustrates only a region corresponding to one pixel. Like the first embodiment, this liquid crystal display 3 has a configuration in which a color filter 15 is provided on the drive substrate 10 side by a so-called COA technique, and has a third electrode 14, which is provided under the color filter 15 and different from an electrode for display driving. Further, the color filter 15 is covered by a planarizing film 16, and a first electrode 30 (pixel electrode) is disposed on the planarizing film 16.

The first electrode 30 is provided for each pixel, and is to be supplied with an electric potential corresponding to an image signal. This first electrode 30 is configured using a transparent conductive film which is, for example, a single-layer film made of either ITO or IZO, or a laminated film made thereof. Here, the first electrode 30 is electrically connected to the third electrode 14, with the color filter 15 in between.

This makes it possible to supply the third electrode 14 with the same potential as that of the first electrode 30, and the first electrode 30 and the third electrode 14 are maintained at the same potential, in the present embodiment as well.

In the present embodiment, a second electrode 33 (counter electrode) is provided on this first electrode 30, and a liquid crystal layer 32 is sealed between the first electrodes 30 and the second electrode 33. On the respective surfaces on the liquid crystal layer 32 side of the first electrode 30 and the second electrode 33, alignment films 31a and 31b are formed. On the second electrode 33, a polarizing plate 35B is laminated with a counter board 34 in between, and a polarizing plate 35A is laminated under a substrate 11. Further, a backlight 36 is provided below the polarizing plate 35A.

The alignment films 31a and 31b control the alignment state of liquid crystal molecules (specifically, liquid crystal molecules in proximity to the alignment films 31a and 31b) in the liquid crystal layer 32. For example, in a case where a liquid crystal driven in a VA (Vertical Alignment) mode is used in the liquid crystal layer 32, vertical alignment films made of polyimide, polysiloxane, or the like, for example, are used as the alignment films 31a and 31b.

The liquid crystal layer 32 is an element controlling the transmittance of light passing therethrough according to a drive voltage, and is driven in, for example, a VA mode, a TN (Twisted Nematic) mode, an IPS (In Plane Switching) mode, an FFS (Fringe Field Switching) mode, or the like.

The second electrode 33 is made of a transparent conductive film like the first electrode 30 described above, and is provided as an electrode common to each pixel. The counter board 34 is a transparent board made of glass, plastic, or the like.

The polarizing plates 35A and 35B are arranged, for example, in a state of crossed Nichol with respect to each other, and block the light from the backlight 36 in a state in which no voltage is applied (OFF state) and allow the light to pass therethrough in a state in which a voltage is applied (ON state).

The backlight 36 is a light source emitting light toward the liquid crystal layer 32, and includes, for example, more than one LED (Light Emitting Diode), CCFL (Cold Cathode Fluorescent Lamp), or the like. The backlight 36 is driven by a backlight driving section 63 to be described later.

### (Peripheral Circuit Configuration)

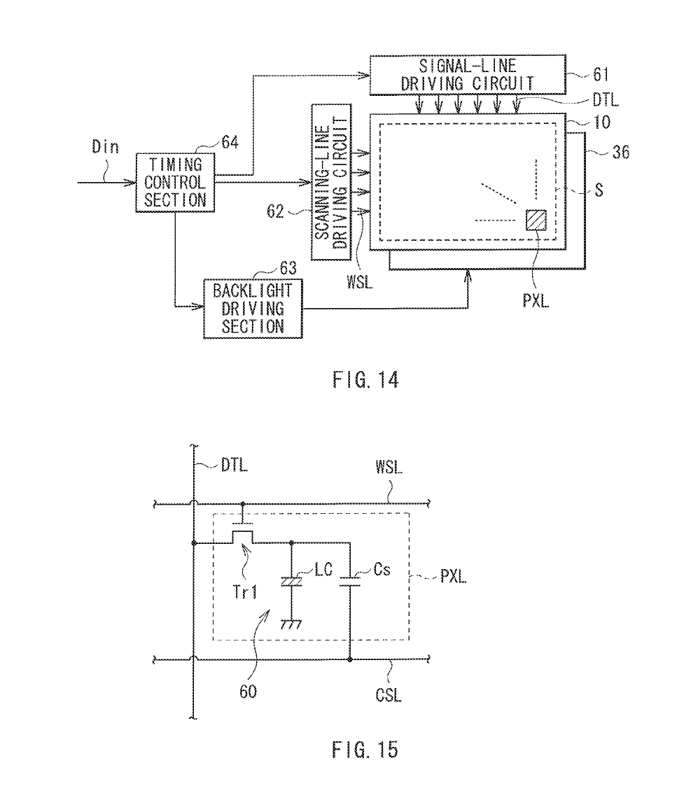

FIG. 14 illustrates a configuration of peripheral circuits for the pixel (PXL) including the liquid crystal display device. As illustrated, in a display region (an effective display region) S on the drive substrate 10, a plurality of pixels (PXL) are two-dimensionally arranged, for example, in the form of a matrix, and around this display region S, a scanning-line driving circuit 62 as well as a signal-line driving circuit 61, a timing control section 64, and the backlight driving section 63 are arranged. Each of the pixels (PXL) is connected to a scanning line WSL and a signal line DTL. It is to be noted that the drive substrate 10 is provided with, for example, a circuit such as an image-signal processing circuit that subjects an image signal to predetermined correction processing, in addition to the above-described elements.

The timing control section 64 controls the timing of driving the scanning-line driving circuit 62 and the signal-line driving circuit 61, and supplies the signal-line driving circuit 61 with an inputted image signal Din. The scanning-line driving circuit 62 line-sequentially drives each pixel, according to timing control performed by the timing control section 64. The signal-line driving circuit 61 supplies each pixel with an image signal based on the image signal Din supplied from the timing control section 64. Specifically, the signal-line driving circuit 61 generates an image signal that is an analog signal by subjecting the image signal Din to D/A (digital-to-analog) conversion, and outputs the generated signal to each pixel.

### (Pixel Circuit Configuration)

FIG. 15 illustrates an example of the circuit configuration of the pixel (PXL). A pixel circuit 60 has, for example, a liquid crystal display device (LC), a transistor Tr1, and a retention capacitive element Cs. One end (the first electrode 30) in the liquid crystal display device (LC) is connected to a drain (or a source) of the transistor Tr1 and one end of the retention capacitive element Cs, whereas the other end (the second electrode 33) is grounded, for example. The other end of the retention capacitive element Cs is connected to a capacitance line CSL. Of the transistor Tr1, a gate is connected to the scanning line WSL, and the sauce (or the drain) is connected to the signal line DTL.

### [Operation and Effects of Liquid Crystal Display 3]

With reference to FIG. 13 to FIG. 15, image display operation in the liquid crystal display 3 will be described. In the liquid crystal display 3, when an image signal is inputted, the scanning-line driving circuit 62 and the signal-line driving circuit 61 drive each of the pixels (PXL) in the display region S for display, and the backlight driving section 63 drives the backlight 36 to emit illumination light toward the drive substrate 10. As a result, the illumination light from the backlight 36 enters the liquid crystal layer 32 after passing through the color filter 15. The incident light is modulated by the application of the drive voltage based on the image signal to the liquid crystal layer 32, and comes out on the counter board 34. In this way, color image display is performed.

Specifically, in the pixel circuit 60 illustrated in FIG. 15, writing operation of the image signal is performed as follows. That is, the scanning-line driving circuit 62 sequentially supplies a scanning signal to the scanning line WSL, and the signal-line driving circuit 61 supplies an image signal based on the inputted image signal Din to the predetermined signal line DTL. As a result, a pixel located at an intersection of the signal line DTL supplied with the image signal and the scanning line WSL supplied with the scanning signal is selected, and a voltage according to the image signal is supplied to the liquid crystal display device (LC) in the pixel. This changes the transmittance in the liquid crystal layer 32, and thereby the above-described display operation is performed.

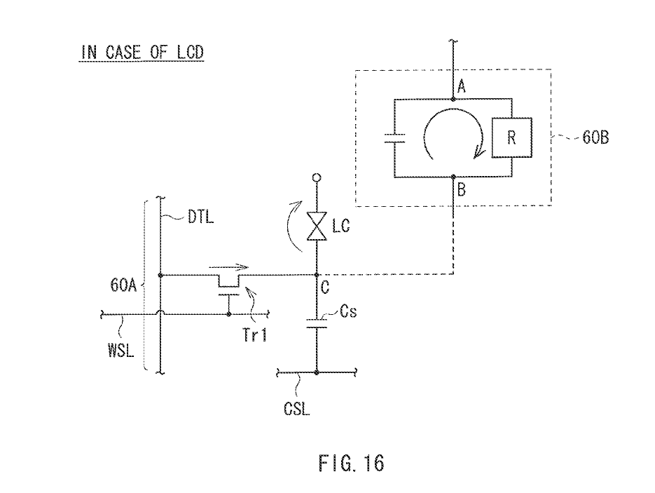

In such a liquid crystal display 3, since the color filter 15 is provided on the drive substrate 10 side, an equivalent circuit 60B based on the color filter 15 is formed at a pixel circuit 60A as illustrated in FIG. 16, like the organic EL display 1 in the first embodiment. Therefore, even in a case where image display is performed using liquid crystal display devices, when the COA technique is adopted, a dielectric dissipation factor and a phenomenon such as movement of carriers and diffusion of impurity ions may be caused by a pigment included in the color filter 15, which leads to a fluctuation in holding potential (an electric potential at a point C) in the pixel circuit 60A, and thereby image degradation may occur. For example, in particular, a fluctuation in holding potential in the pixel G is intense, and there occurs image degradation such as a display screen becoming green in normally white.

In this respect, in the present embodiment, the third electrode 14 is disposed on the drive substrate 10 to face the color filter 15 (have the color filter 15 between the first electrode 30 and the third electrode 14), like the first embodiment. In addition, the third electrode 14 may be supplied with the same potential as that of the first electrode 30, and here, the third electrode 14 is electrically connected to the first electrode 30, and the third electrode 14 is maintained at the same potential as that of the first electrode 30 (the electric potential corresponding to the image signal).

This prevents the electric potential in the point C from fluctuating, by a shielding effect with the third electrode 14 and the first electrode 30, even when a dielectric dissipation factor (and an increase in the dielectric dissipation factor by a photoconductive effect) as described above is produced by the provision of the color filter 15. Further, since the color filter 15 is interposed between equipotential surfaces, the movement of the carriers produced by the photoconductive effect and the movement (diffusion) of the impurity ions and the like are suppressed. As a result, an electric effect of the color filter 15 on the pixel circuit 60 is suppressed, in the present embodiment as well. Furthermore, an effect due to the behavior of the impurity ions as described above may be exerted upon not only the transistor section but also the liquid crystal layer 32 on an upper part, but such an effect may also be reduced by the shielding effect with the third electrode 14 and the first electrode 30.

As described above, in the present embodiment using the liquid crystal display device, it is likewise possible to suppress a fluctuation in the holding potential in the pixel circuit 60 by the electrical shielding effect with the first electrode 30 and the third electrode 14, by providing the third electrode 14 under the color filter 15 in the structure in which the color filter 15 is provided on the drive substrate 10 side. Therefore, the electric effect of the color filter on the pixel circuit may be reduced and thereby degradation in display quality may be suppressed.

Further, since the color filter 15 is interposed between the equipotential surfaces by the supply of the same potential as that of the first electrode 30 to the third electrode 14, the above-described shielding effect may be produced, and moreover, the movements of the carriers and the impurity ions in the color filter 15 may be suppressed. Therefore, it is possible to suppress the electric effect on the pixel circuit 60 more effectively.

### Fourth Embodiment

Next, there will be described a display (a liquid crystal display 4) according to the fourth embodiment of the present disclosure. Elements similar to those of the organic EL display 1 in the first embodiment and those of the liquid crystal display 3 in the third embodiment will be provided with the same reference characters as those of the first and third embodiments, and the description will be omitted as appropriate.

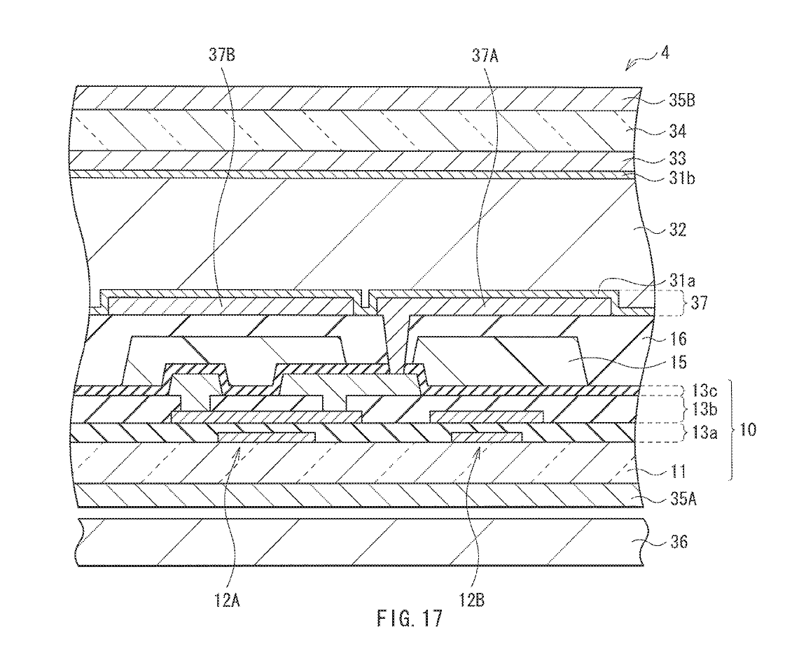

FIG. 17 illustrates a cross-sectional configuration of the liquid crystal display 4. Like the liquid crystal display 3 in the third embodiment described above, the liquid crystal display 4 has a configuration in which a color filter 15 is provided on a drive substrate 10 side by a so-called COA technique, and includes liquid crystal display devices as pixels. Further, the liquid crystal display 4 is similar to the third embodiment, in terms of configurations of peripheral circuits and a pixel circuit.

In the liquid crystal display 4, the color filter 15 is provided on the drive substrate 10, like the liquid crystal display 3 of the third embodiment. On the color filter 15, a planarizing film 16 is provided, and on the planarizing film 16, an electrode layer 37 including a pixel electrode, an alignment film 31a, a liquid crystal layer 32, an alignment film 31b, and a second electrode 33 are laminated.

However, in the present embodiment, a third electrode is not provided under the color filter 15, but is provided above the color filter 15 to face the color filter 15, on the drive substrate 10, unlike the third embodiment. Specifically, the electrode layer 37 disposed on the planarizing film 16 has a part (a first electrode 37A) functioning as the pixel electrode and a part (a third electrode 37B) electrically shielding the color filter 15 (the electrode layer 37 is separated into the first electrode 37A and the third electrode 37B). It is to be noted that an electrode pattern of the first electrode 37A and the third electrode 37B in the electrode layer 37 may be similar to an electrode pattern of the first electrode 23A and the third electrode 23B in the second embodiment described above.

In such an electrode layer 37, the first electrode 37A serving as the pixel electrode is connected to a source/drain electrode 121 of a transistor section 12A, and supplied with an electric potential corresponding to an image signal. On the other hand, the third electrode 37B is electrically separated from this first electrode 37A, while being electrically connected to the second electrode 33, for example, and is supplied with a common potential. Alternatively, the third electrode 37B may be supplied with an electric potential different from the common potential (namely, a positive or negative potential individually set (i.e., a positive or negative potential that is the inverse of an image potential supplied to the first electrode 37A)).

Thanks to the configuration as described above, in the present embodiment, illumination light from a backlight 36 is modulated and thereby color image display is performed, in a manner similar to the third embodiment. Further, since the third electrode 37B is provided in the electrode layer 37 to face the color filter 15, it is possible to reduce an electric effect on a pixel circuit 60 (for example, the write transistor Tr1 in FIG. 16) by reducing or inverting (reversing) the behavior of impurity ions caused by the pigment, for a reason similar to that of the second embodiment. In addition, it is also possible to reduce an adverse effect on the liquid crystal layer 32 caused by the impurity diffusion.

Next, as displays (liquid crystal displays 5 to 7) according to the fifth to seventh embodiments of the present disclosure, liquid crystal displays driven for display in a so-called horizontal electric field mode will be described. Elements similar to those of the organic EL display 1 in the first embodiment and those of the liquid crystal display 3 in the third embodiment will be provided with the same reference characters as those of the first and third embodiments, and the description will be omitted as appropriate.

### Fifth Embodiment

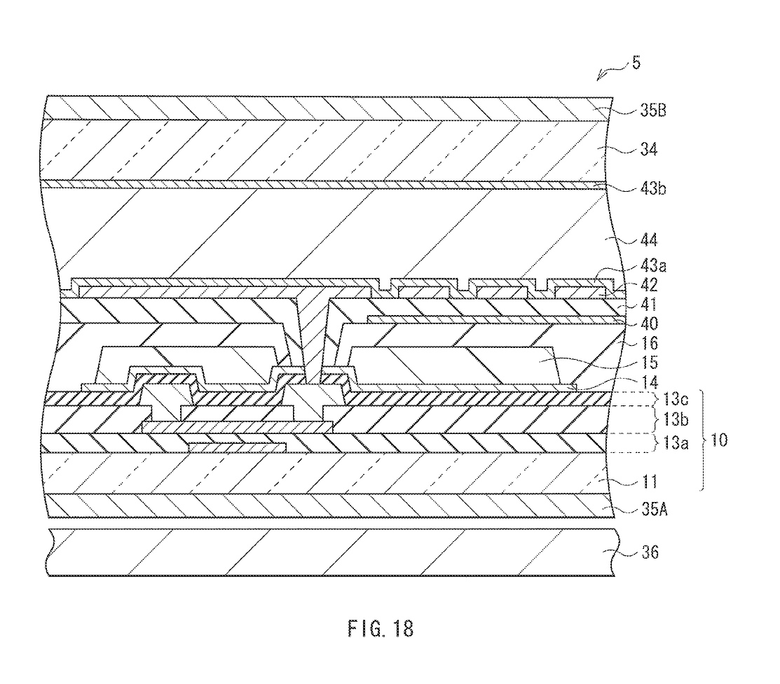

FIG. 18 illustrates a cross-sectional configuration of a liquid crystal display 5. Like the liquid crystal displays 3 and 4 of the third and fourth embodiments described above, the liquid crystal display 5 has a configuration in which a color filter 15 is provided on a drive substrate 10 side by the so-called COA technique, and includes liquid crystal display devices as pixels. Further, the liquid crystal display 5 is also similar to the third embodiment, in terms of configurations of peripheral circuits and a pixel circuit.

In the liquid crystal display 5, like the liquid crystal display 3 of the third embodiment, the color filter 15 is provided on the drive substrate 10, and a planarizing film 16 is formed to cover the color filter 15.

However, in the liquid crystal display 5, display driving is performed in the so-called horizontal electric field mode (FFS mode or IPS mode). In such a liquid crystal display 5, for example, a second electrode 40 serving as a common electrode is disposed on the planarizing film 16, and a first electrode 42 serving as a pixel electrode is disposed on the second electrode 40 with an insulating film 41 in between. On the first electrode 42, a liquid crystal layer 44 is formed and sealed by a counter board 34. Alignment of the liquid crystal layer 44 is controlled by alignment films 43a and 43b.

The first electrode 42 is provided for every pixel, and electrically connected to a sauce (or a drain) of a transistor section 12A, and further, supplied with an electric potential corresponding to an image signal. The first electrode 42 is configured using a transparent conductive film, which is, for example, a single-layer film made of either ITO or IZO, or a laminated film made thereof. The first electrode 42 is patterned to be like the teeth of a comb (have a plurality of slits). A horizontal electric field is formed in the liquid crystal layer 44 through the slits of the first electrode 42. The second electrode 40 is made of a transparent conductive film similar to the above-described first electrode 42, and provided as an electrode common to each pixel. The liquid crystal layer 44 is an element controlling transmittance of light passing therethrough according to a drive voltage, and here, driven based on the horizontal electric field mode such as the IPS mode or the FFS mode.

In the configuration as described above, in the present embodiment, the first electrode 42 is provided on the drive substrate 10 to extend to a region not facing the second electrode 40 (for example, a region facing the transistor section 12A), and in such a region, the third electrode 14 is provided to have the color filter 15 interposed between the third electrode 14 and the first electrode 42. Further, in other region, the third electrode 14 has the color filter 15 interposed between the third electrode 14 and the second electrode 40. The third electrode 14 is electrically connected to the first electrode 42, for example, and maintained at the same potential as a pixel potential (image potential), for instance. Alternatively, although not illustrated, the third electrode 14 may be electrically connected to the second electrode 40 and maintained at the same potential as that of the second electrode 40. Further, the third electrode 14 may be separately supplied with an electric potential, which is different from the image potential and set individually. It is to be noted that here, there is taken, as an example, the configuration in which the third electrode 14 holds the color filter 15 not only with the first electrode 42 in between, but with the second electrode 40 in between, preferably to obtain at least a shielding effect with the first electrode 42 and the third electrode 14 in the region facing the transistor section 12A. More desirably, like the present embodiment, the color filter 15 may be interposed between the second electrode 40 and the third electrode 14 in other region as well.

This prevents the electric potential from fluctuating, by a shielding effect with the third electrode 14 and the first electrode 42 (in addition, a shielding effect with the third electrode 14 and the second electrode 40), even when a dielectric dissipation factor (and an increase in the dielectric dissipation factor by a photoconductive effect) as described above is produced by the provision of the color filter 15. Further, since the color filter 15 is interposed between equipotential surfaces, movement of carriers produced by the photoconductive effect and movement (diffusion) of impurity ions and the like are suppressed. As a result, an electric effect of the color filter 15 on a pixel circuit 60 is suppressed in the present embodiment as well.

As described above, in the present embodiment using the liquid crystal display device in the horizontal electric field mode, it is likewise possible to suppress effects of the fluctuation of the holding potential in the pixel circuit 60, the carrier movement, and the impurity ions, thanks to the electrical shielding effect with the first electrode 42 and the third electrode 14, by providing the third electrode 14 under the color filter 15 in the structure in which the color filter 15 is provided on the drive substrate 10 side. Therefore, the electric effect of the color filter on the pixel circuit may be reduced and thereby degradation in display quality may be suppressed.

### Sixth Embodiment

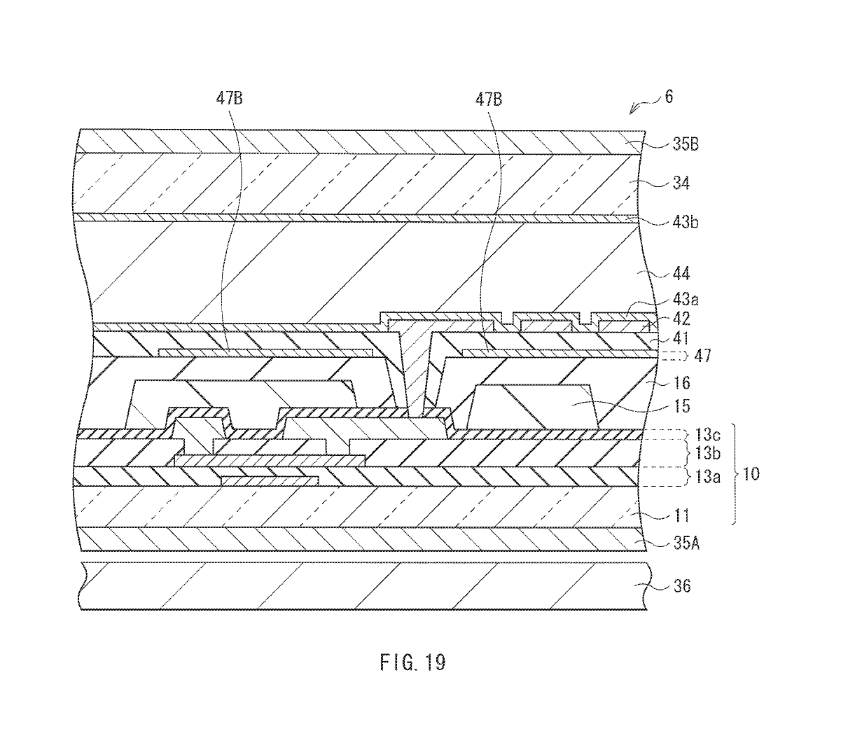

FIG. 19 illustrates a cross-sectional configuration of a liquid crystal display 6. Like the liquid crystal displays of the third to fifth embodiments described above, the liquid crystal display 6 has a configuration in which a color filter 15 is provided on a drive substrate 10 side by the so-called COA technique, and includes liquid crystal display devices driven in the horizontal electric field mode as pixels. In addition, the liquid crystal display 6 uses the liquid crystal display devices in the horizontal electric field mode, in a manner similar to the liquid crystal display 5 of the fifth embodiment. It is to be noted that the liquid crystal display 6 is also similar to the third embodiment in terms of configurations of peripheral circuits and a pixel circuit.

However, in the present embodiment, unlike the fifth embodiment, a third electrode is not provided below the color filter 15, but is provided above the color filter 15 to face the color filter 15, on the drive substrate 10. Specifically, an electrode layer 47 disposed on a planarizing film 16 has a part (a second electrode 47A) functioning as a common electrode and a part (a third electrode 47B) electrically shielding the color filter 15 (the electrode layer 47 is separated into the first electrode 47A and the third electrode 47B).

The third electrode 47B is electrically separated from the second electrode 47A, and provided with an electric potential set individually or the same potential as that of the second electrode 47A.

Thanks to the configuration as described above, in the present embodiment, since the third electrode 47B is provided in the electrode layer 47 to face the color filter 15, it is possible to reduce an electric effect on a pixel circuit, by reducing or inverting (reversing) the behavior of impurity ions caused by a pigment, for a reason similar to those of the second and fourth embodiments.

As descried above, in the present embodiment using the liquid crystal display device in the horizontal electric field mode, in the configuration in which the color filter 15 is provided on the drive substrate 10 side, it is likewise possible to reduce the electric effect on a pixel circuit 60 (for example, the write transistor Tr1 in FIG. 16) by reducing or inverting (reversing) the behavior of the impurity ions and the like caused by the pigment, for a reason similar to that of the second embodiment. Therefore, the electric effect of the color filter on the pixel circuit may be reduced and thereby degradation in display quality may be suppressed.

### APPLICATION EXAMPLES

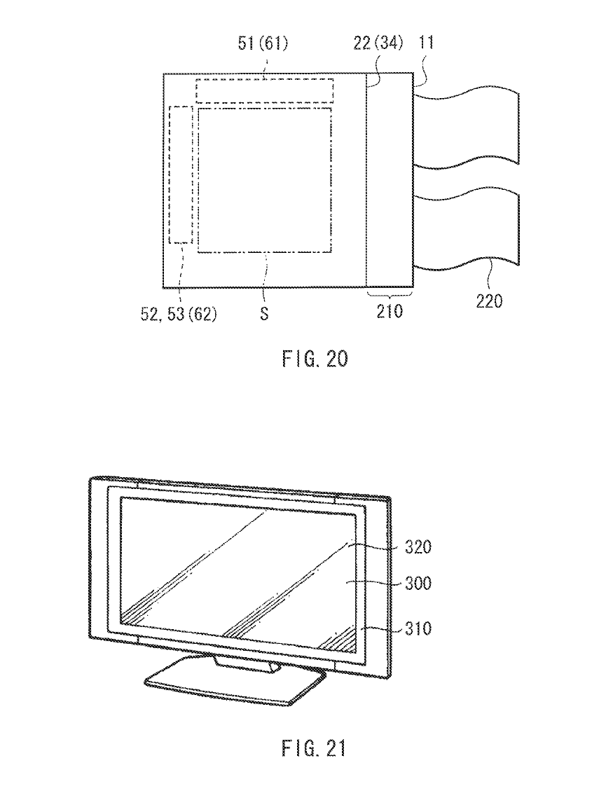

Next, with reference to FIG. 20 to FIG. 25G, there will be described application examples (a module and application examples 1 to 5) of the displays (the organic EL displays 1 and 2, as well as the liquid crystal displays 3 to 6) described in the embodiments and the modification. The display in each of the embodiments and the like described above may be applied to electronic devices in all fields, such as television receivers, digital cameras, laptop computers, portable terminal devices such as portable telephones, and video cameras. In other words, it is possible to apply the display in each of the embodiments and the like to electronic devices in all fields, which display externally-input image signals or internally-generated image signals as still or moving images.

### (Module)

Each of the displays described above is incorporated into various kinds of electronic device such as the application examples 1 to 5 to be described below, as a module as illustrated in FIG. 20, for example. This module is formed, for example, by providing a region 210 exposed at one side of the drive substrate 10 from the sealing substrate 22 (the counter board 34), and forming an external connection terminal (not illustrated) by extending wires of the signal-line driving circuit 51 (61), the power-line driving circuit 52, and the scanning-line driving circuit 53 (the scanning-line driving circuit 62) to the exposed region 210. This external connection terminal may be provided with a flexible printed circuit board (FPC) 220 for input and output of signals.

### Application Example 1

FIG. 21 illustrates an external view of a television receiver according to the application example 1. This television receiver has, for example, an image display screen section 300 that includes a front panel 310 and a filter glass 320, and the image display screen section 300 is equivalent to the display according to each of the embodiments and the like described above.

### Application Example 2

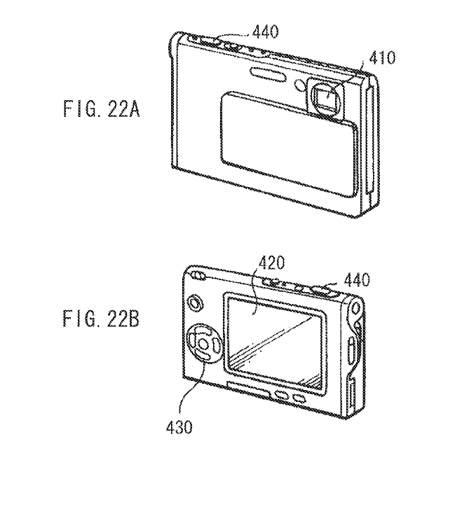

FIGS. 22A and 22B each illustrate an external view of a digital camera according to the application example 2. This digital camera includes, for example, a flash emitting section 410, a display section 420, a menu switch 430, and a shutter release 440, and the display section 420 is equivalent to the display according to each of the embodiments and the like described above.

### Application Example 3

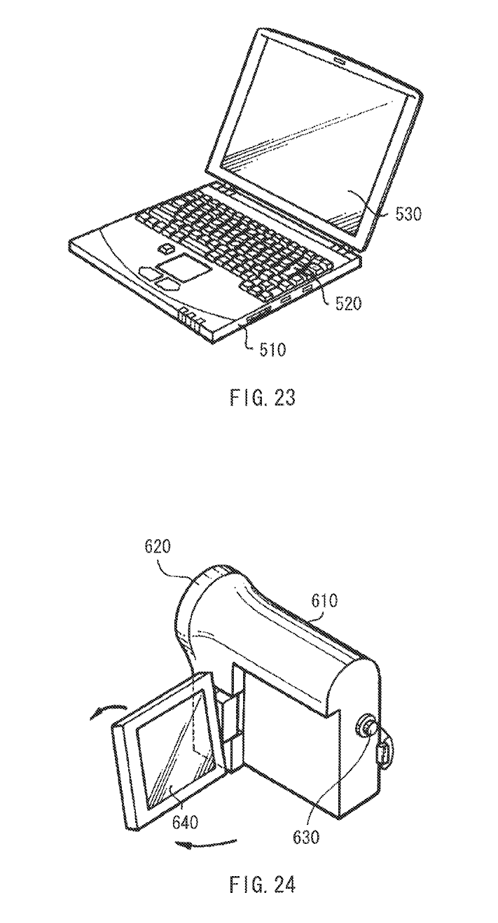

FIG. 23 illustrates an external view of a laptop computer according to the application example 3. This laptop computer includes, for example, a main section 510, a keyboard 520 for entering characters and the like, and a display section 530 that displays an image, and the display section 530 is equivalent to the display according to each of the embodiments and the like described above.

### Application Example 4

FIG. 24 illustrates an external view of a video camera according to the application example 4. This video camera includes, for example, a main section 610, a lens 620 disposed on a front face of this main section 610 to shoot an image of a subject, a start/stop switch 630 used at the time of shooting, and a display section 640. The display section 640 is equivalent to the display according to each of the embodiments and the like described above.

### Application Example 5

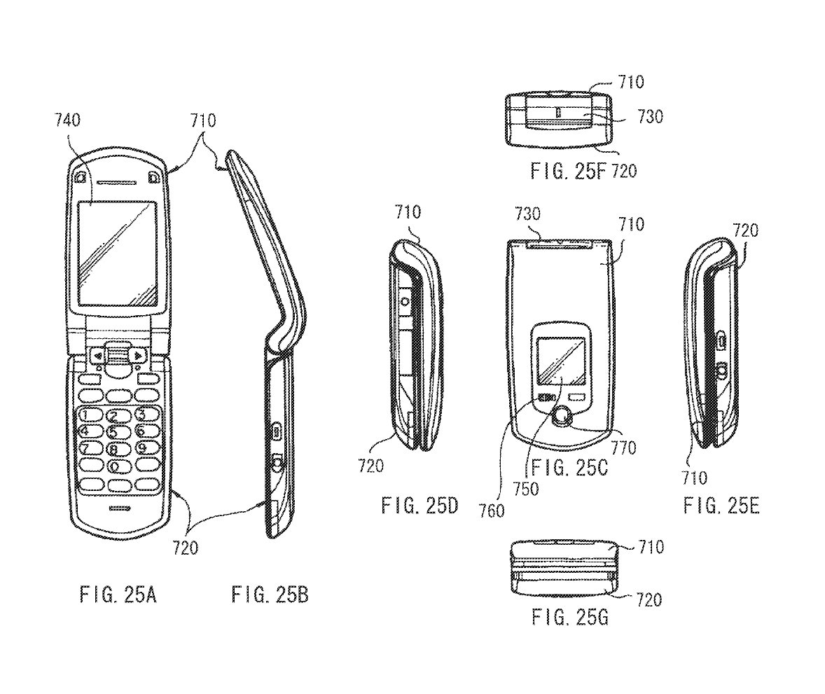

FIGS. 25 to 25G illustrate external views of a portable telephone according to the application example 5. This portable telephone is, for example, a device in which an upper housing 710 and a lower housing 720 are connected by a coupling section (hinge section) 730, and includes a display 740, a sub-display 750, a picture light 760, and a camera 770. The display 740 or the sub-display 750 is equivalent to the display according to each of the embodiments and the like described above.

The present technology has been described by using some embodiments, modification, and application examples, but is not limited to these embodiments and like, and may be variously modified. For example, a film other than each film (each layer) described in the embodiments and the like may be employed, or other layered structure may be provided.

It is possible to achieve at least the following configurations from the above-described example embodiments and the modification of the disclosure.

(1) A display including:

a pixel drive substrate having a color filter;

a display function layer provided on the pixel drive substrate;

a first electrode and a second electrode to supply a drive voltage to the display function layer; and

a third electrode disposed to face the color filter.

(2) The display according to (1), wherein the display function layer is interposed between the first electrode and the second electrode,

the first electrode is disposed for every pixel,

the second electrode is provided to be common to each pixel, and

the third electrode is provided to face the first electrode with the color filter in between.

(3) The display according to (2), wherein the first electrode is suppliable with a first potential corresponding to an image signal, and

the third electrode is suppliable with an electric potential equal to the first potential.

(4) The display according to (2), wherein the first electrode is suppliable with a first potential corresponding to an image signal, and

the third electrode is suppliable with a fixed potential.

(5) The display according to (4), wherein the third electrode is electrically connected to the second electrode.
(6) The display according to (1), wherein the display function layer is interposed between the first electrode and the second electrode,

the first electrode is disposed for every pixel,

the second electrode is provided to be common to each pixel, and

the third electrode is disposed in the same layer as the first electrode, to be electrically independent of the first electrode.

(7) The display according to (6), wherein the first electrode is suppliable with a first potential corresponding to an image signal, and

the third electrode is suppliable with a fixed potential different from the first potential.

(8) The display according to (6), wherein the third electrode is electrically connected to the second electrode.
(9) The display according to (6), wherein the first electrode is suppliable with a positive potential, and the third electrode is suppliable with a negative potential.
(10) The display according to (6), wherein the first electrode is suppliable with a negative potential, and the third electrode is suppliable with a positive potential.
(11) The display according to any one of (1) to (10), wherein the display function layer includes an organic electroluminescent layer.
(12) The display according to any one of (1) to (10), wherein the display function layer includes a liquid crystal layer.
(13) The display according to (1), wherein the second electrode is provided to be common to each pixel,

the first electrode is disposed on the second electrode with an insulating film in between for every pixel, while extending to a region not facing the second electrode,

the display function layer is provided on the first electrode, and driven for display in a horizontal electric field mode, and

the third electrode is provided to face at least the first electrode, of the first electrode and the second electrode, with the color filter in between.

(14) The display according to (1), wherein the second electrode is provided to be common to each pixel,

the first electrode is disposed on the second electrode with an insulating film in between for every pixel,

the display function layer is provided on the first electrode, and driven for display in a horizontal electric field mode, and

the third electrode is disposed in the same layer as the second electrode, to be electrically independent of the second electrode.

(15) An electronic device including

a display including:
a pixel drive substrate having a color filter;
a display function layer provided on the pixel drive substrate;
a first electrode and a second electrode to supply a drive voltage to the display function layer; and
a third electrode disposed to face the color filter.

The present disclosure contains subject matter related to that disclosed in Japanese Priority Patent Application JP 2011-075725 filed in the Japan Patent Office on Mar. 30, 2011, the entire content of which is hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A display comprising:
a pixel drive substrate having a color filter;
a display function layer provided on the pixel drive substrate;
a first electrode and a second electrode to supply a drive voltage to the display function layer; and
a third electrode disposed to face the color filter.

2. The display according to claim 1, wherein the display function layer is interposed between the first electrode and the second electrode,
the first electrode is disposed for every pixel,
the second electrode is provided to be common to each pixel, and
the third electrode is provided to face the first electrode with the color filter in between.

3. The display according to claim 2, wherein the first electrode is suppliable with a first potential corresponding to an image signal, and
the third electrode is suppliable with an electric potential equal to the first potential.

4. The display according to claim 2, wherein the first electrode is suppliable with a first potential corresponding to an image signal, and
the third electrode is suppliable with a fixed potential.

5. The display according to claim 4, wherein the third electrode is electrically connected to the second electrode.

6. The display according to claim 1, wherein the display function layer is interposed between the first electrode and the second electrode,
the first electrode is disposed for every pixel,
the second electrode is provided to be common to each pixel, and
the third electrode is disposed in the same layer as the first electrode, to be electrically independent of the first electrode.

7. The display according to claim 6, wherein the first electrode is suppliable with a first potential corresponding to an image signal, and
the third electrode is suppliable with a fixed potential different from the first potential.

8. The display according to claim 6, wherein the third electrode is electrically connected to the second electrode.

9. The display according to claim 6, wherein the first electrode is suppliable with a positive potential, and the third electrode is suppliable with a negative potential.

10. The display according to claim 6, wherein the first electrode is suppliable with a negative potential, and the third electrode is suppliable with a positive potential.

11. The display according to claim 1, wherein the display function layer includes an organic electroluminescent layer.

12. The display according to claim 1, wherein the display function layer includes a liquid crystal layer.

13. The display according to claim 1, wherein the second electrode is provided to be common to each pixel,
the first electrode is disposed on the second electrode with an insulating film in between for every pixel, while extending to a region not facing the second electrode,
the display function layer is provided on the first electrode, and driven for display in a horizontal electric field mode, and
the third electrode is provided to face at least the first electrode, of the first electrode and the second electrode, with the color filter in between.

14. The display according to claim 1, wherein the second electrode is provided to be common to each pixel,
the first electrode is disposed on the second electrode with an insulating film in between for every pixel,
the display function layer is provided on the first electrode, and driven for display in a horizontal electric field mode, and
the third electrode is disposed in the same layer as the second electrode, to be electrically independent of the second electrode.

15. An electronic device comprising
a display including:
a pixel drive substrate having a color filter;
a display function layer provided on the pixel drive substrate;
a first electrode and a second electrode to supply a drive voltage to the display function layer; and
a third electrode disposed to face the color filter.
